(19) United States
(12) Patent Application Publication
(10) Pub. No.: US 2026/0353821 A1
(43) Pub. Date: Nov. 5, 2026

(54) SEMICONDUCTOR DEVICE AND MANUFACTURING METHOD THEREFOR

(71) Applicant: WUHAN XINXIN SEMICONDUCTOR MANUFACTURING CO., LTD., Wuhan, Hubei (CN)

(72) Inventors: Danqing WEI, Wuhan, Hubei (CN); Qingwei LUO, Wuhan, Hubei (CN)

(21) Appl. No.: 19/123,004

(22) PCT Filed: Dec. 8, 2022
(86) PCT No.: PCT/CN2022/137471

§ 371 Date: Apr. 21, 2025

(30) Foreign Application Priority Data
Oct. 31, 2022 (CN) 202211348912.9

(51) Int. Cl. H10F 30/225; H10W 10/30

(52) U.S. Cl. CPC H10F 30/225; H10W 10/30

(57) ABSTRACT

A semiconductor device includes a substrate having a first surface and a second surface that is opposite to the first surface. The semiconductor device also includes first and second ion-doped regions of opposite doping types. The first ion-doped region extends from the first surface into the substrate, and the second ion-doped region extends from a side of the first ion-doped region away from the first surface towards the second surface. The second ion-doped region contains at least two layers of ion-implanted regions, in a direction from the first surface toward the second surface, dopant ion concentrations of ion-implanted regions of respective layers increase layer by layer, and widths of ion-implanted regions of respective layers increase layer by layer in a direction parallel to the first surface, so that the first and second ion-doped regions constitute a graded junction.

### TECHNICAL FIELD

The present invention relates to the semiconductor integrated circuits (ICs) fabrication field and, in particular, to a semiconductor device and a method for fabricating the same.

### BACKGROUND

The avalanche photodiode (APD) is a P-N junction photodiode, which uses the avalanche multiplication effect of carriers to amplify the photoelectric signal, thereby enhancing the detection sensitivity. Existing APD structure comprises guard-ring and read-through types. Compared to read-through APD, an isolation structure layer with a ring shape is deposited in guard-ring APD, which can prevent the occurrence of an avalanche breakdown at the periphery of the P-N junction under a high reverse bias. Currently, the read-through APD(RAPD), is commonly used, which is typically essentially based on a Read diode (i.e., an N+PIP+ diode) that can easily experience avalanche multiplication. Light is received at the P+ side, I-region is the quasi-intrinsic, lightly-doped region where most incident photons are absorbed to generate charge carriers. The high electric field region for multiplication is concentrated in a narrow area near the P-N+ junction, and the N+ and P+ regions are ion heavily-doped regions with low-resistance and low-voltage used to reduce contact resistance, thereby facilitating connection with the electrodes.

Referring to FIGS. 1a and 1b, a semiconductor device is provided as a P-N junction structure. The P-type material consists of three parts. Photons enter from the P+ layer 11 and penetrate into the intrinsically doped I(p) layer 12, where the material absorbs the light energy and generates primary electron-hole pairs. At this point, the photoelectrons are accelerated by the relatively weak electric field in the depletion region of the I layer 12 and move toward the P-N junction formed by the Player 13 and the N+ layer 14. Here, photos are further accelerated by a strong electric field, leading to the avalanche multiplication effect. Finally, the multiplied photoelectrons reach the N+ layer 14, while the holes are absorbed by the P+ layer 11. The depletion region extends from the P-N junction area all the way to the interface between the I layer 12 and the P+ layer 11. The multiplication region 15 is located between the Player 13 and the N+ layer 14, within the P-N junction. The electric field increases only slightly across the entire depletion region. When the field strength in the depletion region becomes sufficiently high (approximately 3×10\hat{ }5 V/cm), the photogenerated carriers are accelerated to very high velocities. During moving, the carriers collide with atoms in the lattice, causing ionization of the atoms and generating additional electron-hole pairs. These newly generated electrons and holes are also accelerated, leading to further collision and ionization, thereby generating more electron-hole pairs. This physical process is known as the avalanche effect, which multiply and amplify the resulting photocurrent.

However, this semiconductor device is associated with the problems as follows: 1) when a reverse bias voltage is applied to the APD, a potential difference is generated between the P+ layer 11 and the N+ layer 14 only in the vertical direction, and charge carriers outside the horizontal extent of the multiplication region 15 would not be able to reach the multiplication region 15, leading to low detection efficiency; 2) in order to improve the detection efficiency, a width of the N+ layer 14 along the horizontal direction is typically increased to increase width of the multiplication region 15, but this may bring etching-induced defects, damage or the like in peripheral shallow and/or deep trenches of the APD into direct contact with the multiplication region 15, which may possibly lead to a higher dark count rate and a degradation in the device's performance; and 3) in order to enable the semiconductor device to more effectively absorb near-infrared light (905-940 nm), it would be desirable for the semiconductor device to have a considerably large thickness (typically of 7.5 μm or more), but due to a relatively small vertical thickness of the multiplication region 15, charge carriers can create avalanches only after they have diffused a long distance within the intrinsically-doped layer 12 in the depletion region between the P+ layer 11 and the multiplication region 15. As energy loss may occur during the process of diffusion, only a very small number of charge carriers may contribute to the creation of avalanches, additionally lowering the detection efficiency. Furthermore, the diffusion process takes a long time, affecting sensitivity of the semiconductor device.

Therefore, how to improve the detection efficiency remains a problem requiring urgent attention.

### SUMMARY OF THE INVENTION

It is an object of the present invention to provide a semiconductor device with improved detection efficiency and a method for fabricating the same.

To this end, the present invention provides a semiconductor device, comprising:

a substrate having a first surface and a second surface that is opposite to the first surface; and

a first ion-doped region and a second ion-doped region of opposite doping types, wherein the first ion-doped region extends from the first surface into the substrate, and the second ion-doped region extends from a side of the first ion-doped region away from the first surface towards the second surface, wherein the second ion-doped region contains at least two layers of ion-implanted regions, and wherein in a direction from the first surface toward the second surface, dopant ion concentrations of ion-implanted regions of respective layers increase layer by layer, and widths of ion-implanted regions of respective layers increase layer by layer in a direction parallel to the first surface, so that the first and second ion-doped regions constitute a graded junction.

Optionally, the substrate may comprise a bulk substrate and an intrinsically-doped layer formed on the bulk substrate, wherein the first and second ion-doped regions are formed in the intrinsically-doped layer.

Optionally, a doping type of the bulk substrate may be P type, a doping type of the first ion-doped region may be N type, and a doping type of the second ion-doped region may be P type.

Optionally, the ion-implanted regions of respective layers may be stacked one above another.

Optionally, in adjacent ion-implanted regions, the ion-implanted region away from the first ion-doped region may wrap the ion-implanted region closer to the first ion-doped region.

Optionally, a width of a contact area of the second ion-doped region with the first ion-doped region in a direction parallel to the first surface may be less than a width of the first ion-doped region in a direction parallel to the first surface.

Optionally, the semiconductor device may further comprise:

a guard ring formed external to the first ion-doped region.

The present invention also provides a method for fabricating a semiconductor device, which comprises:

providing a substrate having a first surface and a second surface that is opposite to the first surface; and

forming a first ion-doped region and a second ion-doped region of opposite doping types, wherein the first ion-doped region extends from the first surface into the substrate, and the second ion-doped region extends from a side of the first ion-doped region away from the first surface towards the second surface, wherein the second ion-doped region contains at least two layers of ion-implanted regions, and wherein in a direction from the first surface toward the second surface, dopant ion concentrations of ion-implanted regions of respective layers increase layer by layer, and widths of ion-implanted regions of respective layers increase layer by layer in a direction parallel to the first surface, so that the first and second ion-doped regions constitute a graded junction.

Optionally, the ion-implanted regions of respective layers may be stacked one above another.

Optionally, in adjacent ion-implanted regions, the ion-implanted region away from the first ion-doped region may wrap the ion-implanted region closer to the first ion-doped region.

Optionally, the method may further comprise: forming a guard ring external to the first ion-doped region.

The present invention offers the following benefits over the prior art:
1. In the semiconductor device of the present invention, the first and second ion-doped regions are of opposite doping types. The first ion-doped region extends from the first surface into the substrate, and the second ion-doped region extends from the side of the first ion-doped region away from the first surface towards the second surface. The second ion-doped region contains at least two layers of ion-implanted regions, in a direction from the first surface toward the second surface, dopant ion concentrations of ion-implanted regions of respective layers increase layer by layer, and widths of ion-implanted regions of respective layers increase layer by layer in a direction parallel to the first surface, so that the first and second ion-doped regions constitute a graded junction. With this arrangement, the semiconductor device provides higher detection efficiency.
2. In the method of the present invention, the first and second ion-doped regions of opposite doping types are formed. The first ion-doped region extends from the first surface into the substrate, and the second ion-doped region extends from the side of the first ion-doped region away from the first surface towards the second surface. The second ion-doped region contains at least two layers of ion-implanted regions, in a direction from the first surface toward the second surface, dopant ion concentrations of ion-implanted regions of respective layers increase layer by layer, and widths of ion-implanted regions of respective layers increase layer by layer in a direction parallel to the first surface, so that the first and second ion-doped regions constitute a graded junction. With this arrangement, the resulting semiconductor device provides higher detection efficiency.

### BRIEF DESCRIPTION OF THE DRAWINGS

FIG. 1a is a schematic illustration of a semiconductor device.

FIG. 1b schematically illustrates diffusion of charge carriers in the semiconductor device of FIG. 1a.

FIG. 2a is a schematic illustration of a semiconductor device according to an embodiment of the present invention.

FIG. 2b schematically illustrates diffusion of charge carriers in the semiconductor device of FIG. 2a.

FIG. 3 shows a flowchart of a method for fabricating a semiconductor device according to an embodiment of the present invention.

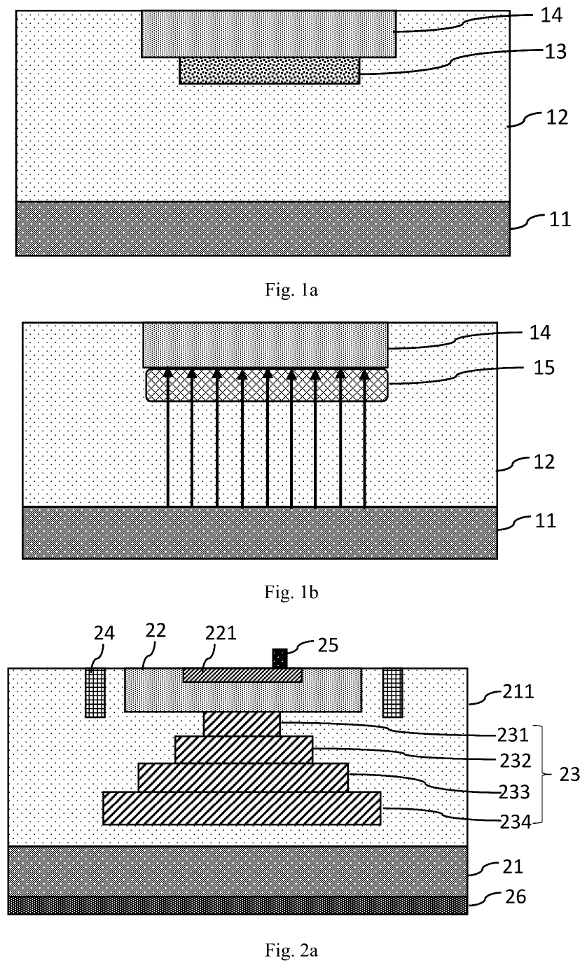

In FIGS. 1a to 3.

11—a P-type bulk substrate; 12—an intrinsically-doped layer; 13—a P-well region; 14—an N-well region; 15—a multiplication region; 21—a bulk substrate; 211—an intrinsically-doped layer; 22—a first ion-doped region; 221—an ion heavily-doped region; 23, a second ion-doped region; 231, a first ion-implanted region; 232, a second ion-implanted region; 233, a third ion-implanted region; 234, a fourth ion-implanted region; 24, a guard ring; 25, a first electrode; 26, a second electrode; and 27, a multiplication region.

### DETAILED DESCRIPTION

Objects, features and advantages of the present invention will become more apparent upon reading the following detailed description of semiconductor devices and fabrication methods proposed herein. Note that the figures are provided in a very simplified form not necessarily drawn to exact scale for the only purpose of helping to explain the disclosed embodiments in a more convenient and clearer way.

In one embodiment of the present invention, a semiconductor device is provided, comprising: a substrate having a first surface and a second surface that is opposite to the first surface; and

a first ion-doped region and a second ion-doped region of opposite doping types, wherein the first ion-doped region extends from the first surface into the substrate, and the second ion-doped region extends from a side of the first ion-doped region away from the first surface towards the second surface, wherein the second ion-doped region contains at least two layers of ion-implanted regions, and wherein in a direction from the first surface toward the second surface, dopant ion concentrations of ion-implanted regions of respective layers increase layer by layer, and widths of ion-implanted regions of respective layers increase layer by layer in a direction parallel to the first surface, so that the first and second ion-doped regions constitute a graded junction.

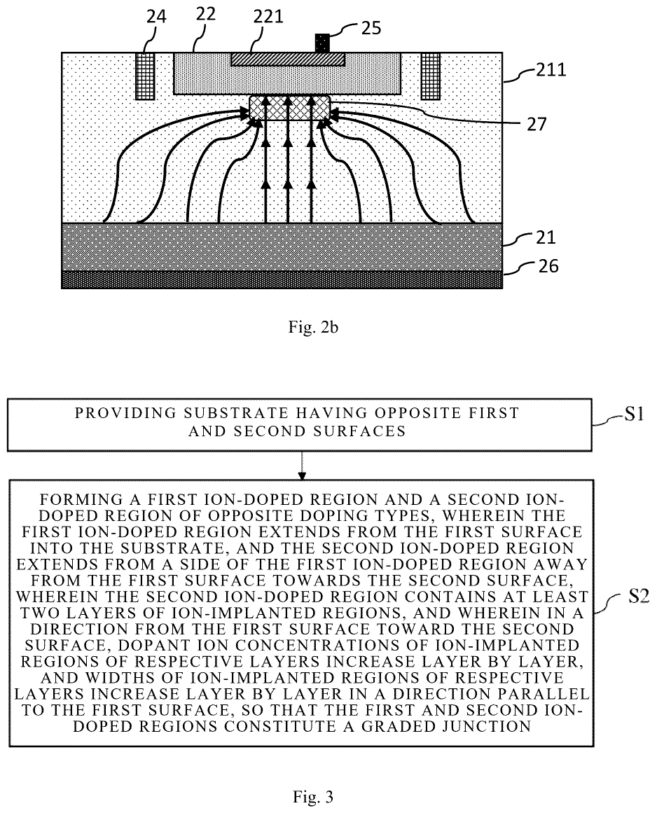

The semiconductor device of this embodiment is described in greater detail below with reference to FIGS. 2a to 2b.

The substrate includes a bulk substrate 21 and an intrinsically-doped layer 211, which is an epitaxial layer formed on the bulk substrate 21 using an epitaxy process. The substrate has a first surface and a second surface that is opposite to the first surface. One side of the intrinsically-doped layer 211 that is away from the bulk substrate 21 is the first surface, and one side of the bulk substrate 21 that is away from the intrinsically-doped layer 211 is the second surface.

The intrinsically-doped layer 211 has a very low level of doping (e.g., lower than 5×10¹⁴ atoms/cm³). As an example, the intrinsically-doped layer 211 may be a semiconductor substrate with unintentional doping, i.e., a P- or N-doped substrate formed only as a consequence of accidental contamination by impurities during fabrication. Alternatively, the intrinsically-doped layer 211 may be a semiconductor substrate with a relative heavy doping level.

The doping types of the bulk substrate 21 and the intrinsically-doped layer 211 may be either the same doping type or different. For example, the doping type of the bulk substrate 21 may be P type, while the doping type of the intrinsically-doped layer 211 may be N type or P type. Alternatively, the doping type of the bulk substrate 21 may be N-type, while the doping type of the intrinsically-doped layer 211 may be N type or P type. Preferably, the bulk substrate 21 is of a P+ type, and the intrinsically-doped layer 211 is of P-type. That is, the bulk substrate 21 is doped at a higher concentration than the intrinsically-doped layer 211.

The substrate may be made of any suitable material well known in the art. For example, it may be made of at least one of silicon (Si), germanium (Ge), silicon germanium (SiGe), silicon carbide (SiC), silicon germanium carbide (SiGeC), indium arsenide (InAs), gallium arsenide (GaAs) and indium phosphide (InP).

The first ion-doped region 22 and the second ion-doped region 23 are formed in the substrate. The first ion-doped region 22 extends from the first surface of the substrate into the substrate, and the second ion-doped region 23 extends from a side of the first ion-doped region 22 away from the first surface towards the second surface.

The first ion-doped region 22 and the second ion-doped region 23 may be formed in the intrinsically-doped layer 211. Since the intrinsically-doped layer 211 has a very low dopant ion concentration, which is much lower than dopant ion concentrations of the first ion-doped region 22 and the second ion-doped region 23, the intrinsically-doped layer 211 may be treated as a neutral region.

The first ion-doped region 22 and the second ion-doped region 23 are of opposite doping types. The second ion-doped region 23, the bulk substrate 21 and the intrinsically-doped layer 211 may be of the same doping type. Preferably, the doping type of the first ion-doped region 22 is an N type and the doping types of the second ion-doped region 23, the bulk substrate 21 and the intrinsically-doped layer 211 are P type. With this arrangement, a P-N junction is formed between the first ion-doped region 22 and the second ion-doped region 23.

The second ion-doped region 23 contains at least two layers of ion-implanted regions, in the direction from the first surface toward the second surface, the dopant ion concentrations of the ion-implanted regions of respective layers increase layer by layer, and the widths of the ion-implanted regions of respective layers increase layer by layer in the direction parallel to the first surface, so that the first ion-doped region 22 and second ion-doped region 23 constitute a graded junction. Each of the ion-implanted regions may have a cross-section of a circular, square, rhombic or other shape, taken parallel to the first surface. The dopant ion concentration of each ion-implanted region may be greater than, equal to, or smaller than the dopant ion concentration of the bulk substrate 21. A multiplication region 27 is formed between the first ion-doped region 22 and the ion-implanted region that is nearest to the first ion-doped region 22.

Since the dopant ion concentrations of the ion-implanted regions increase layer by layer in the direction from the first surface to the second surface, a vertical built-in electric field can be created perpendicular to the first surface between adjacent ion-implanted regions. Moreover, as the vertical built-in electric field is oriented in the same direction as an electric field generated by a reverse bias voltage applied to the photodiode during operation, it can speed up diffusion of charge carriers towards the multiplication region 27, reducing loss of charge carriers in the process of diffusion, increasing the probability of creating avalanches and improving detection efficiency of the semiconductor device.

In particular, in order to enable the semiconductor device to more effectively absorb near-infrared light (905-940 nm), it would be desirable for the substrate to have a considerably large thickness (typically of 7.5 μm or more), which results in a large thickness of the intrinsically-doped layer 211. However, due to a relatively small thickness of the multiplication region 27, charge carriers can create avalanches only after they have diffused a long distance in a depletion region (from the P-N junction to an interface of the intrinsically-doped layer 211 and the bulk substrate 21). According to this embodiment, the vertical built-in electric field can accelerate diffusion of charge carriers and reduce their energy loss in the depletion region, allowing more charge carriers to reach the multiplication region 27 and thereby increasing the probability of creating avalanches.

As the widths of the ion-implanted regions of respective layers in a direction parallel to the first surface increase layer by layer in the direction from the first surface to the second surface, a built-in electric field formed between adjacent ion-implanted regions includes not only a vertical built-in electric field perpendicular to the first surface but also a curved built-in electric field not parallel to the vertical built-in electric field. The curved built-in electric field can drive charge carriers in peripheral regions outside the widthwise extents of the ion-implanted regions in the intrinsically-doped layer 211 into the multiplication region 27 (as indicated by the curved arrows of FIG. 2b), increasing utilization of charge carriers and improving the semiconductor device's detection efficiency.

An orthographic projection of the vertical built-in electric field on the first surface coincides with an orthographic projection of the ion-implanted region nearest to the first ion-doped region 22 on the first surface. The curved built-in electric field is located around the periphery of the vertical built-in electric field, and its orthographic projection on the first surface coincides or overlaps with an orthographic projection of the ion-implanted region farthest from the first ion-doped region 22 on the first surface.

As required, the ion-implanted regions may be arranged in various arrangements, including but not limited to, a wrapped arrangement in which they are wrapped one in another, and a stacked arrangement in which they are stacked one above another. In case of the ion-implanted regions comprising the wrapped arrangement, doping depths of the ion-implanted regions of respective layers that are perpendicular to the first surface extend from the interface of the first ion-doped region 22 and the second ion-doped region 23 towards the second surface. That is, in adjacent ion-implanted regions, the ion-implanted region away from the first ion-doped region 22 is located at not only a bottom surface of the ion-implanted region proximal to the first ion-doped region 22 but also side faces of the ion-implanted region proximal to the first ion-doped region 22. That is, the ion-implanted region away from the first ion-doped region 22 is trough-shaped and wraps the ion-implanted region closer to the first ion-doped region 22. In case of the ion-implanted regions comprising the stacked arrangement, the doping depths of the ion-implanted regions of respective layers extend from the interface of adjacent ion-implanted regions toward the second surface in the direction perpendicular to the first surface, and are distributed in a step-like manner, resembling a hemispherical shape. In adjacent ion-implanted regions, the ion-implanted region away from the first ion-doped region 22 is located at only a bottom surface of the ion-implanted region proximal to the first ion-doped region 22 but not side faces of the ion-implanted region proximal to the first ion-doped region 22. The ion-implanted regions may share a common axis, and in adjacent ion-implanted regions, the ion-implanted regions may have either the same or different doping depths in direction perpendicular to the first surface.

The width of the first ion-doped region 22 in a direction parallel to the first surface may lie between maximum and minimum ones of the widths of the ion-implanted regions of respective layers parallel to the first surface. Alternatively, the width of the first ion-doped region 22 in a direction parallel to the first surface may be greater than the maximum one of the widths of the ion-implanted regions of respective layers in a direction parallel to the first surface. Still alternatively, the width of the first ion-doped region 22 in a direction parallel to the first surface may be less than the minimum one of the widths of the ion-implanted regions in a direction parallel to the first surface. In one embodiment, a width of a contact area of the second ion-doped region 23 with the first ion-doped region 22 in a direction parallel to the first surface is less than the width of the first ion-doped region 22 in a direction parallel to the first surface, in order to avoid any breakdown at lateral peripheral edges of the photodiode. In case of the ion-implanted regions of respective layers comprising the stacked arrangement, the width of the contact area of the second ion-doped region 23 with the first ion-doped region 22 in a direction parallel to the first surface is equal to a width of the ion-implanted region nearest to the first ion-doped region 22 in a direction parallel to the first surface. Accordingly, the width of the ion-implanted region nearest to the first ion-doped region 22 in a direction parallel to the first surface is less than the width of the first ion-doped region 22 in a direction parallel to the first surface direction. In case of the ion-implanted regions of respective layers comprising the wrapped arrangement, the width of the contact area of the second ion-doped region 23 with the first ion-doped region 22 in a direction parallel to the first surface is equal to the width of the ion-implanted region farthest from the first ion-doped region 22 in a direction parallel to the first surface. Accordingly, the width of the ion-implanted region farthest from the first ion-doped region 22 in a direction parallel to the first surface is less than the width of the first ion-doped region 22 in a direction parallel to the first surface.

Additionally, the greater the width of the ion-implanted region nearest to the first ion-doped region 22 in a direction parallel to the first surface, the greater a width of the multiplication region 27 in a direction parallel to the first surface. The greater the width of the ion-implanted region farthest from the first ion-doped region 22 in a direction parallel to the first surface, the greater the number of charge carriers that are located at the peripheral regions of the ion-implanted regions in the intrinsically-doped layer 211 diffuses into the multiplication region 27. In this way, under the action of the curved built-in electric field, charge carriers located at peripheral regions of the multiplication region 27 can also diffuse into the multiplication region 27. This increases the utilization of charge carriers, improving the detection efficiency of the semiconductor device.

In the embodiment of FIGS. 2a to 2b, the second ion-doped region 23 contains four layers of ion-implanted regions stacked layer by layer in the direction from the first surface to the second surface, namely, a first ion-implanted region 231, a second ion-implanted region 232, a third ion-implanted region 233 and a fourth ion-implanted region 234 that are stacked layer by layer. The dopant ion concentrations of the first ion-implanted region 231 to the fourth ion-implanted region 234 progressively increase, the widths of the first ion-implanted region 231 to the fourth ion-implanted region 234 progressively increase in the direction parallel to the first surface. The present invention is not limited to any particular number of ion-implanted regions in the second ion-doped region 23, and they can be configured as desired.

The semiconductor device further includes an ion heavily-doped region 221 formed at a surface of the first ion-doped region 22. The ion heavily-doped region 221 is of the same doping type as the first ion-doped region 22.

The semiconductor device further includes a guard ring 24 formed external to the first ion-doped region 22. The guard ring 24 surrounds the first ion-doped region 22, and the guard ring 24 is spaced apart from the first ion-doped region 22 by the substrate. Preferably, a depth of the guard ring 24 is not less than a depth of the first ion-doped region 22.

The guard ring 24 may be a shallow trench isolation (STI) structure, or a doped ring. In the latter case, the doping type of the doped ring may be N type or P type.

The semiconductor device further includes an annular deep trench isolation (DTI) structure (not shown), which is formed in the substrate external to the guard ring 24. The DTI structure is spaced apart from the guard ring 24 by the substrate. The DTI structure is configured to obtain isolation between adjacent photodiodes, to avoid crosstalk.

A depth of the DTI structure is not less than a depth of the first ion-doped region 22.

The DTI structure is formed in an annular trench (not shown) in the substrate and includes an insulating layer (not shown) covers the inner surfaces of the annular trench and a conductive layer (not shown) filling the annular trench.

According to embodiments of the present invention, the multiplication region 27 can be expanded without increasing the width of the first ion-doped region 22 in a direction parallel to the first surface, it prevents the width of the multiplication region 27 from being excessively large which could result in defects or damage generated during the etching of trenches for the formation of the STI structure and the DTI structure from directly contacting the multiplication region 27, which may possibly lead to a higher dark count rate and a degradation in the device's performance.

The semiconductor device further includes a first electrode 25 and a second electrode 26. The first electrode 25 is formed on the ion heavily-doped region 221, and the second electrode 26 is formed on the first or second surface of the substrate. In the embodiment of FIGS. 2a to 2b, the second electrode 26 is formed on the second surface of the substrate, and the ion heavily-doped region 221 is configured for external connection of the first ion-doped region 22, thereby reducing the contact resistance when a voltage is applied to the first ion-doped region 22 through the first electrode 25. A reverse bias voltage can be applied to the photodiode through the first electrode 25 and the second electrode 26.

In summary, the present invention provides a semiconductor device comprising: a substrate having a first surface and a second surface that is opposite to the first surface; and first and second ion-doped regions of opposite doping types, the first ion-doped region extending from the first surface into the substrate, the second ion-doped region extending from a side of the first ion-doped region away from the first surface towards the second surface, the second ion-doped region comprising at least two layers of ion-implanted regions, in the direction from the first surface toward the second surface, the dopant ion concentrations of the ion-implanted regions of respective layers increase layer by layer, and the widths of the ion-implanted regions of respective layers increase layer by layer in the direction parallel to the first surface, so that the first and second ion-doped regions constitute a graded junction. This semiconductor device exhibits higher detection efficiency.

In one embodiment of the present invention, there is provided a method for fabricating a semiconductor device. FIG. 3 shows a flowchart of the method for fabricating a semiconductor device according to an embodiment of the present invention. As shown, the method for fabricating a semiconductor device includes:

step S1: providing a substrate having a first surface and a second surface that is opposite to the first surface; and

step S2: forming first and second ion-doped regions of opposite doping types, the first ion-doped region extending from the first surface into the substrate, the second ion-doped region extending from a side of the first ion-doped region away from the first surface towards the second surface, the second ion-doped region comprising at least two layers ion-implanted regions, in the direction from the first surface toward the second surface, the dopant ion concentrations of the ion-implanted regions of respective layers increase layer by layer, and the widths of the ion-implanted regions of respective layers increase layer by layer in the direction parallel to the first surface, so that the first and second ion-doped regions constitute a graded junction.

The method for fabricating the semiconductor device of this embodiment is described in greater detail below with reference to FIGS. 2a to 2b.

In step S1, a substrate is provided, which has a first surface and a second surface that is opposite to the first surface.

The substrate includes a bulk substrate 21 and an intrinsically-doped layer 211, which is an epitaxial layer formed on the bulk substrate 21 using an epitaxy process. One side of the intrinsically-doped layer 211 that is away from the bulk substrate 21 is the first surface, and one side of the bulk substrate 21 that is away from the intrinsically-doped layer 211 is the second surface.

The doping types of the bulk substrate 21 and the intrinsically-doped layer 211 may be either the same or opposite. For example, the doping type of the bulk substrate 21 may be P type, while the doping types of the intrinsically-doped layer 211 may be N type or P type. Alternatively, the doping type of the bulk substrate 21 may be N type, while the doping types of the intrinsically-doped layer 211 may be N type or P type. Preferably, the bulk substrate 21 is a P+ substrate, and the intrinsically-doped layer 211 is a P-layer. The bulk substrate 21 is doped at a higher concentration than the intrinsically-doped layer 211.

The substrate may be made of any suitable material well known in the art. For example, it may be made of at least one of silicon (Si), germanium (Ge), silicon germanium (SiGe), silicon carbide (SiC), silicon germanium carbide (SiGeC), indium arsenide (InAs), gallium arsenide (GaAs) and indium phosphide (InP).

In step S2, a first ion-doped region 22 and a second ion-doped region 23 are formed with opposite doping types. The first ion-doped region 22 and the second ion-doped region 23 are formed in the substrate. The first ion-doped region 22 extends from the first surface of the substrate into the substrate, and the second ion-doped region 23 extends from a side of the first ion-doped region 22 away from the first surface towards the second surface.

The first ion-doped region 22 and the second ion-doped region 23 may be formed in the intrinsically-doped layer 211. Since the intrinsically-doped layer 211 has a very low dopant ion concentration, which is much lower than dopant ion concentrations of the first ion-doped region 22 and the second ion-doped region 23, the intrinsically-doped layer 211 may be treated as a neutral region.

The first ion-doped region 22 and the second ion-doped region 23 are of opposite doping types. The second ion-doped region 23, the bulk substrate 21 and the intrinsically-doped layer 211 may be of the same doping type. Preferably, the doping type of the first ion-doped region 22 is an N type, and the doping types of the second ion-doped region 23, the bulk substrate 21 and the intrinsically-doped layer 211 are P type. With this arrangement, a P-N junction is formed between the first ion-doped region 22 and the second ion-doped region 23.

The second ion-doped region 23 contains at least two layers of ion-implanted regions, in the direction from the first surface toward the second surface, the dopant ion concentrations of the ion-implanted regions of respective layers increase layer by layer, and the widths of the ion-implanted regions of respective layers increase layer by layer in the direction parallel to the first surface, so that the first 22 and second 23 doped regions constitute a graded junction. A multiplication region 27 is formed between the first ion-doped region 22 and the ion-implanted region nearest to the first ion-doped region 22.

Since the dopant ion concentrations of the ion-implanted regions increase layer by layer in the direction from the first surface to the second surface, a vertical built-in electric field can be created perpendicular to the first surface between adjacent ion-implanted regions. Moreover, as the vertical built-in electric field is oriented in the same direction as an electric field generated by a reverse bias voltage applied to the photodiode during operation, it can speed up diffusion of charge carriers towards the multiplication region 27, reducing loss of charge carriers in the process of diffusion, increasing the probability of creating avalanches and improving detection efficiency of the semiconductor device.

As the widths of the ion-implanted regions of respective layers in a direction parallel to the first surface increase layer by layer in the direction from the first surface to the second surface, a built-in electric field formed between adjacent ion-implanted regions includes not only a vertical built-in electric field perpendicular to the first surface but also a curved built-in electric field not parallel to the vertical built-in electric field. The curved built-in electric field can drive charge carriers in peripheral regions outside the widthwise extents of the ion-implanted regions in the intrinsically-doped layer 211 into the multiplication region 27 (as indicated by the curved arrows of FIG. 2b), increasing utilization of charge carriers and improving the semiconductor device's detection efficiency.

As required, the ion-implanted regions may be arranged in various arrangements, including but not limited to, a wrapped arrangement in which they are wrapped one in another, and a stacked arrangement in which they are stacked one above another. In case of the ion-implanted regions comprising the wrapped arrangement, doping depths of the ion-implanted regions of respective layers that are perpendicular to the first surface extend from the interface of the first ion-doped region 22 and the second ion-doped region 23 towards the second surface. That is, in adjacent ion-implanted regions, the ion-implanted region away from the first ion-doped region 22 is located not only a bottom surface of the ion-implanted region proximal to the first ion-doped region 22 but also side faces of the ion-implanted region proximal to the first ion-doped region 22. That is, the ion-implanted region away from the first ion-doped region 22 is trough-shaped and wraps the ion-implanted region closer to the first ion-doped region 22. In case of the ion-implanted regions comprising the stacked arrangement, the doping depths of the ion-implanted regions of respective layers extend from the interface of adjacent ion-implanted regions toward the second surface in the direction perpendicular to the first surface, and are distributed in a step-like manner, resembling a hemispherical shape. In adjacent ion-implanted regions, the ion-implanted region away from the first ion-doped region 22 is located at only a bottom surface of the ion-implanted region proximal to the first ion-doped region 22 but not side faces of the ion-implanted region proximal to the first ion-doped region 22. The ion-implanted regions may share a common axis, and in adjacent ion-implanted regions, the ion-implanted regions may have either the same or different doping depths in direction perpendicular to the first surface.

The width of the first ion-doped region 22 in a direction parallel to the first surface may lie between maximum and minimum ones of the widths of the ion-implanted regions of respective layers parallel to the first surface. Alternatively, the width of the first ion-doped region 22 in a direction parallel to the first surface may be greater than the maximum one of the widths of the ion-implanted regions of respective layers in a direction parallel to the first surface. Still alternatively, the width of the first ion-doped region 22 in a direction parallel to the first surface may be less than the minimum one of the widths of the ion-implanted regions of respective layers in a direction parallel to the first surface. In one embodiment, a width of a contact area of the second ion-doped region 23 with the first ion-doped region 22 in a direction parallel to the first surface is less than the width of the first ion-doped region 22 in a direction parallel to the first surface, in order to avoid any breakdown at lateral peripheral edges of the photodiode. In case of the ion-implanted regions of respective layers comprising the stacked arrangement, the width of the contact area of the second ion-doped region 23 with the first ion-doped region 22 in a direction parallel to the first surface is equal to a width of the ion-implanted region nearest to the first ion-doped region 22 in a direction parallel to the first surface. Accordingly, the width of the ion-implanted region nearest to the first ion-doped region 22 in a direction parallel to the first surface is less than the width of the first ion-doped region 22 in a direction parallel to the first surface direction. In case of the ion-implanted regions of respective layers comprising the wrapped arrangement, the width of the contact area of the second ion-doped region 23 with the first ion-doped region 22 in a direction parallel to the first surface is equal to the width of the ion-implanted region farthest from the first ion-doped region 22 in a direction parallel to the first surface. Accordingly, the width of the ion-implanted region farthest from the first ion-doped region 22 in a direction parallel to the first surface is less than the width of the first ion-doped region 22 in a direction parallel to the first surface.

Additionally, the greater the width of the ion-implanted region nearest to the first ion-doped region 22 in a direction parallel to the first surface, the greater a width of the multiplication region 27 in a direction parallel to the first surface. The greater the width of the ion-implanted region farthest from the first ion-doped region 22 in a direction parallel to the first surface, the greater the number of charge carriers that are located at the peripheral regions of the ion-implanted regions in the intrinsically-doped layer 211 diffuses into the multiplication region 27. In this way, under the action of the curved built-in electric field, charge carriers located at peripheral regions of the multiplication region 27 can also diffuse into the multiplication region 27. This increases the utilization of charge carriers, improving the detection efficiency of the semiconductor device.

In the embodiment of FIGS. 2a to 2b, the second ion-doped region 23 contains four layers of ion-implanted regions stacked layer by layer in the direction from the first surface to the second surface, namely, a first ion-implanted region 231, a second ion-implanted region 232, a third ion-implanted region 233 and a fourth ion-implanted region 234 that are stacked layer by layer. The dopant ion concentrations of the first ion-implanted region 231 to the fourth ion-implanted region 234 progressively increase, the widths of the first ion-implanted region 231 to the fourth ion-implanted region 234 progressively increase in the direction parallel to the first surface. The present invention is not limited to any particular number of ion-implanted regions in the second ion-doped region 23, and they can be configured as desired.

Ion implantation processes may be employed to form the first ion-doped region 22 and then the second ion-doped region 23, or to form the second ion-doped region 23 and then the first ion-doped region 22.

For example, in case of the ion-implanted regions of respective layers comprising the stacked arrangement, the formation of the second ion-doped region 23 may include, first of all, forming a patterned mask layer (not shown) on the first surface of the substrate, the patterned mask layer comprises an opening configured to allow implantation of the ions to the substrate. When sequentially forming ion-implanted regions of respective layers along the direction from the first surface toward the second surface, the width of the opening can be progressively widen by replacing the photomask multiple times. After each adjustment of the opening width, ion implantation is performed into the substrate using the patterned mask layer with the adjusted opening width as a mask. The energy and dose of the ion implantation are gradually increased with each increase of the opening width, ensuring that each ion implantation forms a layer of an ion-implanted region with a predetermined depth and width. Alternatively, when sequentially forming ion-implanted regions of respective layers along the direction from the second surface toward the first surface, the width of the opening can be progressively narrowed by replacing the photomask multiple times. After each adjustment of the opening width, ion implantation is performed into the substrate using the patterned mask layer with the adjusted opening width as a mask. The energy and dose of the ion implantation are gradually decreased with each decrease of the opening width, ensuring that each ion implantation forms a layer of an ion-implanted region with a predetermined depth and width.

Further, each ion implantation step may be followed by an annealing treatment performed on the substrate to repair fractures or damage in the semiconductor lattice induced by ion collisions.

The method for fabricating the semiconductor device further includes forming an ion heavily-doped region 221 on a surface of the first ion-doped region 22 using an ion implantation process. The ion heavily-doped region 221 is of the same doping type as the first ion-doped region 22.

The method for fabricating the semiconductor device further includes forming a guard ring 24 external to the first ion-doped region 22, the guard ring 24 surrounds the first ion-doped region 22 and is spaced apart from the first ion-doped region 22 by the substrate.

Preferably, a depth of the guard ring 24 is not less than a depth of the first ion-doped region 22.

The guard ring 24 may be a shallow trench isolation (STI) structure, or a doped ring. In the latter case, the doping type of the doped ring may be N type or P type doped. The method for fabricating the semiconductor device further includes forming an annular DTI structure (not shown) in the substrate external to the guard ring 24, the DTI structure is spaced apart from the guard ring 24 by the substrate. The DTI structure is configured to obtain isolation between adjacent photodiodes, to avoid crosstalk.

A depth of the DTI structure is not less than a depth of the first ion-doped region 22.

The DTI structure is formed in an annular trench (not shown) in the substrate and includes an insulating layer (not shown) covers the inner surfaces of the annular trench and a conductive layer (not shown) filling the annular trench.

According to embodiments of the present invention, the multiplication region 27 can be expanded without increasing the width of the first ion-doped region 22 in a direction parallel to the first surface, it prevents the width of the multiplication region 27 from being excessively large which could result in defects or damage generated during the etching of trenches for the formation of the STI structure and the DTI structure from directly contacting the multiplication region 27, which may possibly lead to a higher dark count rate and a degradation in the device's performance.

The method for fabricating the semiconductor device further includes forming a first electrode 25 on the ion heavily-doped region 221 and a second electrode 26 on the first or second surface of the substrate. In the embodiment of FIGS. 2a to 2b, the second electrode 26 is formed on the second surface of the substrate, and the ion heavily-doped region 221 is configured for external connection of the first ion-doped region 22, thereby reducing the contact resistance when a voltage is applied to the first ion-doped region 22 through the first electrode 25. A reverse bias voltage can be applied to the photodiode through the first electrode 25 and the second electrode 26.

In summary, the present invention provides a method for fabricating a semiconductor device, which comprises: providing a substrate having a first surface and a second surface that is opposite to the first surface; and forming first and second ion-doped regions of opposite doping types, the first ion-doped region extending from the first surface into the substrate, the second ion-doped region extending from a side of the first ion-doped region away from the first surface towards the second surface, the second ion-doped region comprising at least two layers of ion-implanted, in the direction from the first surface toward the second surface, the dopant ion concentrations of the ion-implanted regions of respective layers increase layer by layer, and the widths of the ion-implanted regions of respective layers increase layer by layer in the direction parallel to the first surface, so that the first ion-doped region 22 and second ion-doped region 23 constitute a graded junction. A semiconductor device with improved detection efficiency can be obtained according to this method.

The description presented above is merely that of some preferred embodiments of the present invention and is not intended to limit the scope thereof in any sense. Any and all changes and modifications made by those of ordinary skill in the art based on the above teachings fall within the scope of the invention.

1. A semiconductor device, comprising:
a substrate having a first surface and a second surface that is opposite to the first surface; and
a first ion-doped region and a second ion-doped region of opposite doping types, wherein the first ion-doped region extends from the first surface into the substrate, and the second ion-doped region extends from a side of the first ion-doped region away from the first surface towards the second surface, wherein the second ion-doped region contains at least two layers of ion-implanted regions, and wherein in a direction from the first surface toward the second surface, dopant ion concentrations of ion-implanted regions of respective layers increase layer by layer, and widths of ion-implanted regions of respective layers increase layer by layer in a direction parallel to the first surface, so that the first and second ion-doped regions constitute a graded junction.

2. The semiconductor device of claim 1, wherein the substrate comprises a bulk substrate and an intrinsically-doped layer formed on the bulk substrate, wherein the first and second ion-doped regions are formed in the intrinsically-doped layer.

3. The semiconductor device of claim 2, wherein: a doping type of the bulk substrate is P type; a doping type of the first ion-doped region is N type; and a doping type of the second ion-doped region is P type.

4. The semiconductor device of claim 1, wherein the ion-implanted regions of respective layers are stacked one above another.

5. The semiconductor device of claim 1, wherein in adjacent ion-implanted regions, the ion-implanted region away from the first ion-doped region wraps the ion-implanted region closer to the first ion-doped region.

6. The semiconductor device of claim 1, wherein a width of a contact area of the second ion-doped region with the first ion-doped region in a direction parallel to the first surface is less than a width of the first ion-doped region in a direction parallel to the first surface.

7. The semiconductor device of claim 1, wherein further comprising:
a guard ring formed external to the first ion-doped region.

8. A method for fabricating a semiconductor device, comprising:
providing a substrate having a first surface and a second surface that is opposite to the first surface; and
forming a first ion-doped region and a second ion-doped region of opposite doping types, wherein the first ion-doped region extends from the first surface into the substrate, and the second ion-doped region extends from a side of the first ion-doped region away from the first surface towards the second surface, wherein the second ion-doped region contains at least two layers of ion-implanted regions, and wherein in a direction from the first surface toward the second surface, dopant ion concentrations of ion-implanted regions of respective layers increase layer by layer, and widths of ion-implanted regions of respective layers increase layer by layer in a direction parallel to the first surface, so that the first and second ion-doped regions constitute a graded junction.

9. The method for fabricating the semiconductor device of claim 8, wherein the ion-implanted regions of respective layers are stacked one above another.

10. The method for fabricating the semiconductor device of claim 8, wherein in adjacent ion-implanted regions, the ion-implanted region away from the first ion-doped region wraps the ion-implanted region closer to the first ion-doped region.

11. The method for fabricating the semiconductor device of claim 8, further comprising:
forming a guard ring external to the first ion-doped region.

12. The semiconductor device of claim 1, wherein a multiplication region is formed between the first ion-doped region and the ion-implanted region that is nearest to the first ion-doped region.

13. The semiconductor device of claim 1, wherein a built-in electric field is formed between adjacent ion-implanted regions, and wherein the built-in electric field includes a vertical built-in electric field perpendicular to the first surface and a curved built-in electric field not parallel to the vertical built-in electric field.

14. The semiconductor device of claim 1, wherein a width of the first ion-doped region in a direction parallel to the first surface lies between a maximum width and a minimum width of the ion-implanted regions of respective layers in a direction parallel to the first surface.

15. The semiconductor device of claim 1, further comprising a first electrode and a second electrode, wherein the first electrode is formed on an ion heavily-doped region, and the second electrode is formed on the first or second surface of the substrate.

16. The method for fabricating the semiconductor device of claim 8, a multiplication region is formed between the first ion-doped region and the ion-implanted region that is nearest to the first ion-doped region.

17. The method for fabricating the semiconductor device of claim 8, wherein a built-in electric field is formed between adjacent ion-implanted region, and wherein the built-in electric field includes a vertical built-in electric field perpendicular to the first surface and a curved built-in electric field not parallel to the vertical built-in electric field.

18. The method for fabricating the semiconductor device of claim 8, wherein a width of the first ion-doped region in a direction parallel to the first surface lies between a maximum width and a minimum width of the ion-implanted regions of respective layers in a direction parallel to the first surface.

19. The method for fabricating the semiconductor device of claim 8, further comprising forming a first electrode and a second electrode, wherein the first electrode is formed on an ion heavily-doped region, and the second electrode is formed on the first or second surface of the substrate.

20. The method for fabricating the semiconductor device of claim 9, wherein formation of the second ion-doped region comprises:
forming a patterned mask layer on the first surface of the substrate, wherein the patterned mask layer comprises an opening configured to allow implantation of ions to the substrate;
progressively widening or narrowing a width of the opening by replacing a photomask multiple times, and performing an ion implantation into the substrate using the patterned mask layer with an adjusted opening width as a mask.
